(19) United States
(12) Patent Application Publication
(10) Pub. No.: US 2026/0101469 A1
(43) Pub. Date: Apr. 9, 2026

(54) DUAL REDUNDANT COLD PLATE

(71) Applicant: Lockheed Martin Corporation, Bethesda, MD (US)

(72) Inventors: Viktor Hromyk, Stratford, CT (US); Nicholas C. Visinski, Stratford, CT (US); Emre Gurpinar, Stratford, CT (US)

(21) Appl. No.: 18/909,371

(22) Filed: Oct. 8, 2024

(51) Int. Cl. H05K 7/20; B64D 47/00

(52) U.S. Cl. CPC H05K 7/20254; B64D 47/00; H05K 7/20272

(57) ABSTRACT

A cold plate, for cooling an electronic component, includes a first end, a second end, opposite the first end, and a top face extending between the first end and the second end. The top face is configured to engage the electronic component. A first set of conduits extends between the first end and the second end and includes a first inlet conduit, a first outlet conduit, and at least one first microchannel between the first inlet conduit and the first outlet conduit. A second set of conduits extends between the first end and the second end, and includes a second inlet conduit, a second outlet conduit, and at least one second microchannel between the second inlet conduit and the second outlet conduit. The first set of conduits is fluidly isolated from the second set of conduits.

### FIELD OF INVENTION

The concepts described herein relate to cooling systems and cold plates used to cool electronic components. In some examples, the electronic components are critical electronics on aircrafts. In some examples, the aircraft is a vertical take-off and landing VTOL aircraft.

### BACKGROUND

Cold plates are conventionally used to cool heat loads, such as electronic components, by transporting heat via a circulating fluid. In aerospace applications, the electronic components are avionics and include critical components (e.g., components which the failure could have a catastrophic effect). Cold plates used to cool avionics and critical components need to be lightweight and compact, while still providing the needed heat transfer to maintain the temperature of the control electronics below a critical temperature.

### SUMMARY

In one aspect, a cold plate, for cooling an electronic component, includes a first end, a second end, opposite the first end, and a top face extending between the first end and the second end. The top face is configured to engage the electronic component. A first set of conduits extends between the first end and the second end and includes a first inlet conduit, a first outlet conduit, and at least one first microchannel between the first inlet conduit and the first outlet conduit. A second set of conduits extends between the first end and the second end, and includes a second inlet conduit, a second outlet conduit, and at least one second microchannel between the second inlet conduit and the second outlet conduit. The first set of conduits is fluidly isolated from the second set of conduits.

In another aspect, a cooling system, for cooling avionics, includes a cold plate having a first end, a second end, and a top face configured to contact one or more avionic components. A first cooling loop includes a first pump and a first set of conduits extending through the cold plate. A second cooling loop includes a second pump and a second set of conduits extending through the cold plate. Fluid in the first cooling loop travels through the cold plate in a first direction and fluid in the second cooling loop travels through the cold plate in a second direction, opposite the first direction.

In another aspect, a method for cooling an avionic component includes mounting the avionic component to a top face of a cold plate. A first cooling fluid is circulated through a first loop, including activating a first pump to circulate the first cooling fluid, and circulating the first cooling fluid through a set of first conduits in the cold plate to transfer heat from the avionic component through the top face to the first cooling fluid. A second cooling fluid is circulated through a second loop, including activating a second pump to circulate the second cooling fluid, and circulating the second cooling fluid through a set of second conduits in the cold plate to transfer heat from the avionic component through the top face to the second cooling fluid. The second loop is fluidly isolated from the first loop.

Other aspects will become apparent by consideration of the detailed description and accompanying drawings.

### BRIEF DESCRIPTION OF THE DRAWINGS

FIG. 1 is a schematic view of an aircraft having an avionics system and a cold plate for cooling electronic components of the avionics system.

FIG. 2 is a perspective view of the cold plate and exemplary electronic components of the avionics system of FIG. 1.

FIG. 3 is a schematic view of a cooling system including the cold plate of FIG. 2.

FIG. 4 is a perspective view of the interior of the cold plate of FIG. 2 including a first embodiment of an internal fluid system with multiple stages.

FIG. 5 is a top view of one of the stages of the internal fluid system of FIG. 4.

FIG. 6 is a perspective view of one of the stages of the internal fluid system of FIG. 4.

FIG. 7A is a first cross-sectional view of the cold plate of FIG. 4.

FIG. 7B is a second cross-sectional view of the cold plate of FIG. 4.

FIG. 8 is a top view of the internal fluid system of FIG. 4.

FIG. 9 is a perspective view of another embodiment of an internal fluid system for use with the cold plate of FIG. 2.

FIG. 10 is a perspective view of another embodiment of an internal fluid system for use with the cold plate of FIG. 2.

FIG. 11 is a perspective view of one stage of another embodiment of an internal fluid system for use with the cold plate of FIG. 2.

### DETAILED DESCRIPTION

Power electronics refers to the application of solid-state electronics related to the control and conversion of electrical power. This conversion is typically performed by silicon, silicon carbide, and gallium nitride as well as other semiconductor devices that are packaged into power modules. Due to electrical power conversion inefficiency and other factors, power modules are known to generate heat. The heat generated by the power modules can result in a reduction in the reliability of the power module performance.

An additional factor for thermal management relates to the packaging of several devices in small form factors. The power density at which the devices, and thus the module, can reliably operate therefore depends on the ability to remove this generated heat. One common form of thermal management of power electronics is through heat sinks. Heat sinks operate by transferring the heat away from the heat source of the power module, thereby maintaining the heat source at a lower relative temperature. There are various types of heat sinks known in the thermal management field including air-cooled and liquid-cooled devices as well as phase change devices to ride out transient heat dissipations.

One example of the thermal management of a power module includes the attachment of a heat sink with embedded passages (tubes) to provide liquid cooling of the power module, also referred to as a cold plate. The cold plate may be a metallic structure or a metal plated structure, using metals such as aluminum or copper with high thermal transfer. A cooling medium is passed through the tubes to cool the power module. The heat sink may be coupled to the power module base with a thermal interface material (TIM) dispersed there between. The thermal interface material may comprise thermal greases, compliant thermal pads, phase change materials, or the like.

Before any embodiments are explained in detail, it is to be understood that the embodiments described herein are directed to a cold plate for an electronic component where the cold plate is a single piece component with embedded internal conduits for coolant. For purposes of illustration, the present disclosure will be described with respect to a cold plate for cooling a power module of an aircraft. It will be understood, however, that aspects of the disclosure described herein are not so limited and may have general applicability within the field of electronics.

Before any embodiments are explained in detail, it is to be understood that the embodiments described herein are provided as examples and the details of construction and the arrangement of the components described herein or illustrated in the accompanying drawings should not be considered limiting. All directional references (e.g., radial, axial, proximal, distal, upper, lower, upward, downward, left, right, lateral, front, back, top, bottom, above, below, vertical, horizontal, clockwise, counterclockwise, upstream, downstream, forward, aft, etc.) are only used for identification purposes to aid the reader's understanding of the present disclosure, and do not create limitations, particularly as to the position, orientation, or use of aspects of the disclosure described herein. Also, it is to be understood that the phraseology and terminology used herein is for the purpose of description and should not be regarded as limited. The use of “including,” “comprising” or “having” and variations thereof herein is meant to encompass the items listed thereafter and equivalents thereof as well as additional items. The terms “mounted,” “connected” and “coupled” are used broadly and encompass both direct and indirect mounting, connecting, and coupling. Further, “connected” and “coupled” are not restricted to physical or mechanical connections or couplings. In some operable embodiments according to the disclosure, the drawings are to scale, although not-to-scale embodiments are also contemplated.

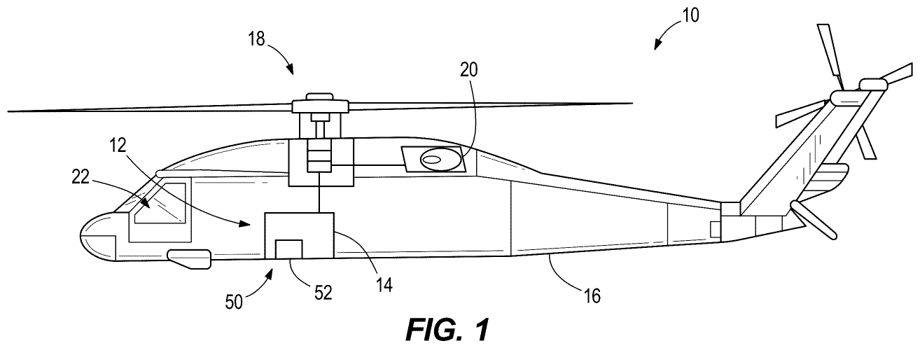

FIG. 1 schematically illustrates an aircraft 10 with an avionics system 12 including avionics or avionic components for use in the operation of the aircraft 10. The avionics system 12 is illustrated as at least partially positioned in an on-board electronics control box 14. The aircraft 10 is illustrated as a rotary wing aircraft with vertical take-off and landing capabilities (e.g., a helicopter). In other embodiments, the aircraft 10 may be any type of aircraft including, but not limited to, fixed-wing, rotating-wing, rocket, commercial aircraft, personal aircraft, and military aircraft.

The illustrated aircraft 10 includes a main frame 16, a rotor assembly 18, and a power source 20. The illustrated aircraft 10 is a piloted aircraft and includes a cockpit 22 formed in the main frame 16 which includes a user interface allowing a pilot to provide flight control input to operate the aircraft 10. In other embodiments, the flight control input may be provided to the aircraft 10 remotely, or by a control system in other ways. In the illustrated embodiment, the electronics control box 14 is positioned in the main frame 16 of the aircraft 10. In other embodiments, the aircraft 10 may be configured differently and the avionics system 12 may be housed in other locations. The avionics system 12 includes a plurality of electronic components. At least one thermal management system or cooling system 50 is positioned in the aircraft 10 for managing the temperature of the electronic components of the avionics system 12.

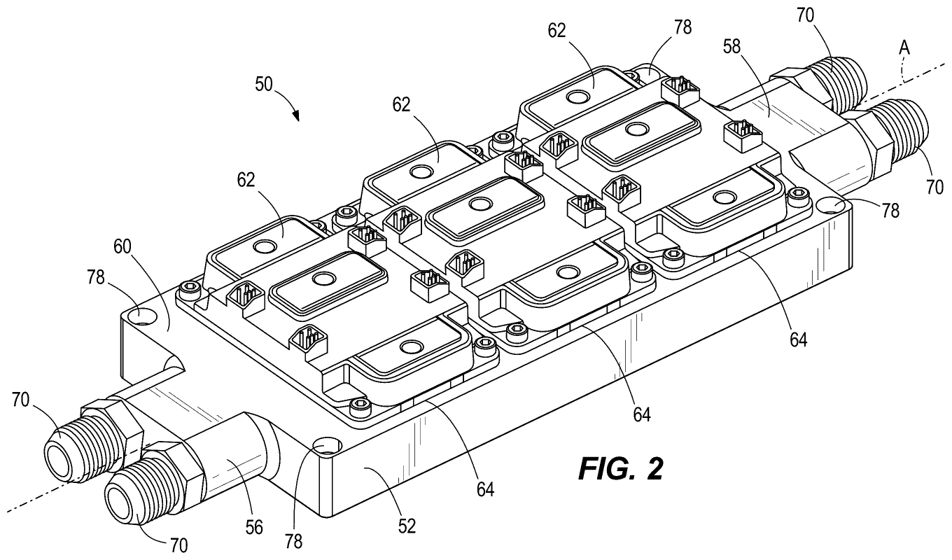

Turning now to FIGS. 2-8, the cooling system 50 includes a cold plate 52 for providing localized cooling to at least one electronic component 62 of the avionics system 12. In the illustrated embodiment, the cold plate 52 provides cooling to a set of three electronic components 62. In some embodiments, the electronic components 62 may each be the same type of component. In some embodiments, the electronic components 62 may each be a different type of component. In the illustrated embodiment, each of the electronic components 62 is a power module. In other embodiments, other types of electronic components 62 may be cooled. In some embodiments, the power module is a semi-conductor device including silicon carbide and is part of an inverter system for handling high voltage and current levels. The electronic component 62 may generate steady-state or transient heat loads during operation. The illustrated electronic components 62 are meant to be exemplary and are not intended to limit the disclosure.

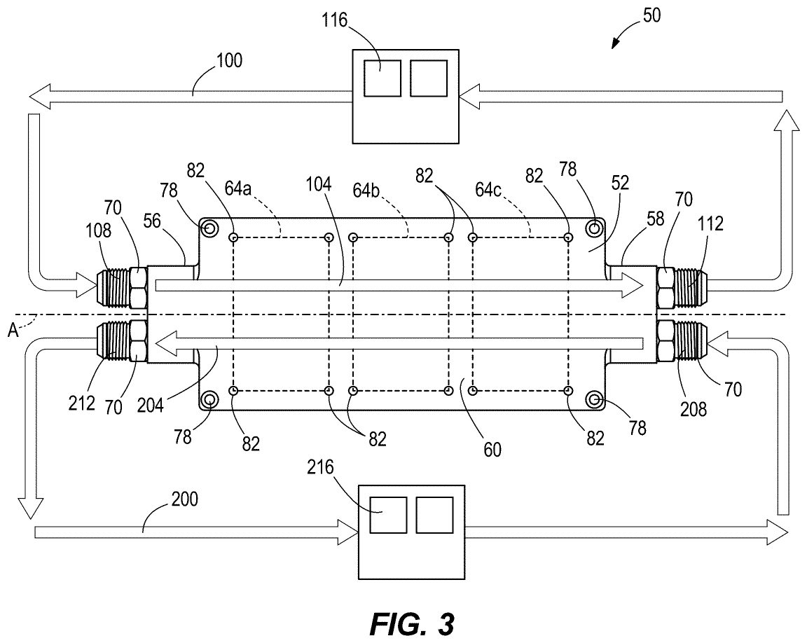

With reference to FIG. 2, the cold plate 52 is a unitary body defining internal fluid passageways (discussed later herein). The cold plate 52 extends along a main axis A between a first end 56 and a second end 58. The cold plate 52 includes a plurality of ports 70 that fluidly couple to the internal fluid passageways. In the illustrated embodiment, the ports 70 include hose fittings for coupling to hoses or pipes of the cooling system 50. However, the term ‘port’ and any references to the port 70 may refer to either the connector or to the opening itself interchangeably. In other embodiments, other connection methods are used to connect the rest of the cooling system 50 to the cold plate 52. The cold plate 52 defines a top face 60 extending between the first end 56 and the second end 58. The electronic components 62 are coupled to the cold plate 52 adjacent the top face 60 so that the electronic components 62 are thermally coupled to the cold plate 52 for heat transfer therebetween. In the illustrated embodiment, the top face 60 defines a set of three cooling interfaces 64 (FIG. 3) and each of the electronic components 62 is positioned adjacent one of the cooling interfaces 64 to engage the top face 60. In some embodiments, the cold plate 52 may be double sided and the top face 60 may include a first set of interfaces 64 and the cold plate 52 may include another face (e.g., a bottom face) including a second set of interfaces 64. In some embodiments, the cold plate 52 is positioned in the electronics control box 14 to cool the electronic components 62 of the avionics system 12. In other embodiments, the cold plate 52 may be positioned elsewhere in the aircraft 10. The cold plate 52 may be coupled to the aircraft 10 by fasteners extending through mounting holes, (e.g., mounting holes 78). In other embodiments, the cold plate 52 may be mounted or supported in the aircraft 10 in other ways.

With continued reference to FIG. 2, the electronic components 62 may be standardized packages with known mounting features. The cold plate 52 may include mounting openings (e.g., mounting holes 82 in FIG. 3) matched to the mounting features of the electronic components 62 to allow for easy assembly of the electronic component 62 to the top face 60 of the cold plate 52. In other embodiments, the cold plate 52 may include brackets or adapters configured to help couple the electronic components 62 to the top face 60. The electronic component 62 may include sub-components mounted on a substrate (e.g., a PCB board) including mounting features. The substrate may be formed of a material that conducts heat but does not conduct electricity and thus prevents short circuits of the electronic component 62. In one embodiment, the electronic component 62 may be coupled to the cold plate 52 using thermal interface material (TIM) instead of or in addition to fasteners. In another embodiment, the electronic component 62 may be coupled to an adapter using TIM and the adapter may be fastened to the cold plate 52. In still further embodiments, the electronic components 62 may be otherwise coupled to cold plate 52. The electronic component 62 is coupled to the cold plate 52 such that a heat load of the electronic component 62 is adjacent the associated cooling interface 64 and is in thermal communication with the cold plate 52.

With reference to FIG. 3, a portion of the cooling system 50 is schematically illustrated. The cooling system 50 includes the cold plate 52 and further includes two redundant cooling loops 100, 200 each configured to circulate cooling fluid through the cold plate 52 to transfer heat away from the electronic components 62. The cooling loops 100, 200 are fluidly isolated from each other. In some embodiments, the cooling loops 100, 200 circulate the same type of cooling fluid. In other embodiments, the first cooling loop 100 may circulate a different cooling fluid than the second cooling loop 200. The cooling loops 100, 200 may circulate any suitable cooling fluid. In one non-limiting example, both cooling loops 100, 200 circulate a mixture of water and ethylene glycol. In other embodiments, the cooling fluid may include other liquids, a gaseous medium, a phase change material, or any other fluid with suitable thermal properties. The first cooling loop 100 may circulate fluid at a first flow rate through the cold plate 52 and the second cooling loop 200 may circulate fluid at a second flow rate through the cold plate 52. In some embodiments, the first flow rate and second flow rate may be the same. Accordingly, the cooling fluid flows through the cooling loops 100, 200 in the cold plate 52 to cool the attached electronic components 62. The cooling loops 100, 200 are operable independently from each other.

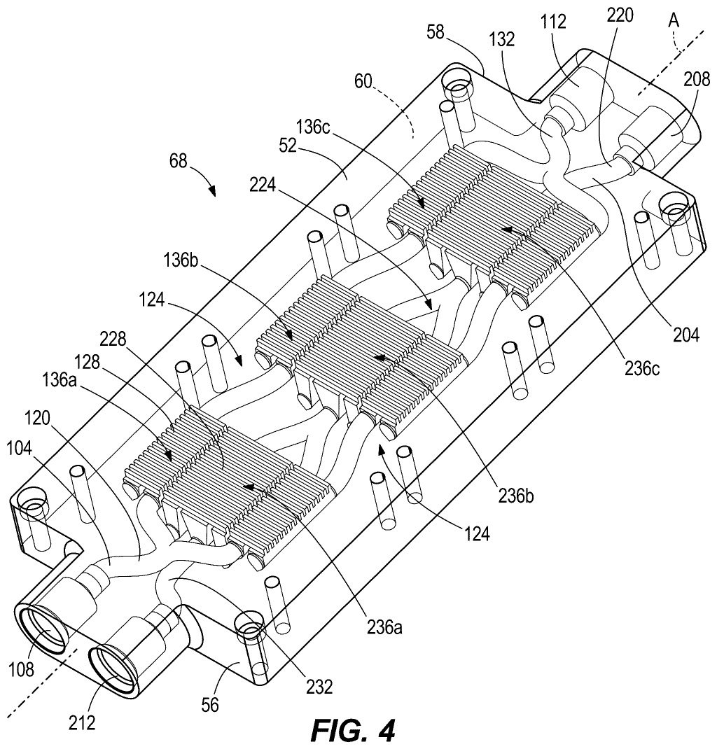

With continued reference to FIG. 3, the cold plate 52 includes an internal fluid system 68 (FIG. 4) having a plurality of internal passageways. In the illustrated embodiment, the internal fluid system 68 includes a first cooling manifold 104 and a second cooling manifold 204. In the illustrated embodiment, both cooling manifolds 104, 204 travel under each of three cooling interfaces 64a, 64b, and 64c. The first cooling manifold 104 extends through the cold plate 52 between the first end 56 and the second end 58. The first cooling loop 100 extends through the first manifold 104 of the cold plate 52 and travels through the cold plate 52 in a first direction, such that one of the ports 70 on the first end 56 forms a first inlet port 108 and one of the ports 70 on the second end 58 forms a first outlet port 112. The first direction extends generally along the axis A from the first end 56 to the second end 58.

Therefore, the cooling loop 100 travels past the cooling interface 64a, then the cooling interface 64b, then the cooling interface 64c. The first cooling loop 100 may include a first pump 116 and other components (e.g., a reservoir, a heat exchanger, etc.) not discussed herein used to transmit and store the fluid as well as to dissipate heat before recirculating the fluid.

The second cooling manifold 204 extends between the first end 56 and the second end 58. The second cooling loop 200 extends through the second manifold 204 of the cold plate 52 and travels through the cold plate 52 in a second direction, opposite the first direction. The second direction extends generally along the axis A from the second end 58 to the first end 56. Thus, one of the ports 70 on the second end 58 forms a second inlet port 208 and one of the ports 70 on the first end 56 forms a second outlet port 212. Therefore, the cooling loop 200 travels past the cooling interface 64c, then the cooling interface 64b, then the cooling interface 64a. The second cooling loop 200 also includes a second pump 216 and other components (e.g., a reservoir, a heat exchanger, etc.) not discussed herein used to transmit and store the fluid as well as to dissipate heat before recirculating the fluid. In some embodiments, fluid may flow through the cooling loops 100, 200 in the same direction such that the ports 70 on the first end 56 are both inlet ports and the ports 70 on the second end 58 are both outlet ports.

With continued reference to FIG. 3, the first cooling loop 100 is fluidly isolated from the second cooling loop 200 and is operable independently from the second cooling loop 200. In other words, the first cooling loop 100 and the second cooling loop 200 are redundant, to accommodate a faulted condition in which one loop is not operational. Both cooling loops 100, 200 underlie a portion of each of the cooling interfaces 64 and the attached electronic components 62. Both cooling loops 100, 200 are designed to have a heat transfer efficiency (i.e., be able to effectively cool a heat load of a certain level) that is high enough that, in a faulted condition, the remaining operational cooling loop is capable of cooling the electronic components 62 and preventing overheating without the other loop. In other words, each cooling loop 100, 200 provides sufficient heat transfer to cool the electronic components 62 without the other loop. In some embodiments, the cooling loops 100, 200 may be coupled to sensors that connect to a control system to alert the pilot to a fault condition. The fault condition may call for the aircraft to conduct an emergency landing to allow for repairs to the faulty loop. In some embodiments, each cooling loop 100, 200 is capable of handling the heat load of the electronic components 62 indefinitely during a faulted condition. In some embodiments, the cooling loops 100, 200 may be able to handle the heat load of the electronic components indefinitely when both loops 100, 200 are operational, and may be able to handle the heat load for a set period of time when only one loop is operational. The set period of time may correspond to an amount of time required to execute an emergency landing or may be longer.

With reference to FIGS. 4-8, the internal passageways and the first and second manifolds 104, 204 of the cold plate 52 are illustrated and described. The internal passageways are formed in the body of the cold plate 52. In other words, the first and second cooling manifolds 104, 204 are formed by the negative space within the solid body of the cold plate 52. In other embodiments, the conduits of the manifolds 104, 204 may be formed in other ways. For example, in some embodiments the conduits of the manifolds 104, 204 may be formed from tubes or pipes. FIG. 4 illustrates the internal faces of the cold plate 52 that surround the negative space to form the internal passageways, with the external faces of the cold plate 52 transparent.

As seen in FIG. 4, the first manifold 104 extends between the first inlet port 108 and the first outlet port 112. The first manifold 104 includes a first inlet conduit 120 that divides into a pair of first branches 124 extending in parallel and including a plurality of first microchannels 128, and a first outlet conduit 132. The first inlet conduit 120 is coupled to the first inlet port 108 and is fluidly coupled to an upstream end of each of the branches 124. Cooling fluid flows through the pair of branches 124 in parallel and flows through the plurality of first microchannels 128 in each of the pair of branches 124. The first microchannels 128 are positioned adjacent the top face 60 of the cold plate 52 to increase heat transfer between the top face 60 and the cooling fluid. The branches 124 are both fluidly coupled to the first outlet conduit 132, which is coupled to the first outlet port 112. The first manifold 104 therefore defines a portion of the first cooling loop 100. With continued reference to FIG. 4, the first manifold 104 includes a plurality of cooling stages 136, each positioned adjacent one of the plurality of cooling interfaces 64 (FIG. 2). In the illustrated embodiment, there are three cooling stages 136a, 136b, 136c to correspond to the three cooling interfaces 64a, 64b, 64c (FIG. 3). In embodiments with a different number of cooling interfaces 64 the first manifold 104 may include a corresponding number of cooling stages 136. Each cooling stage 136 includes a portion of the plurality of first microchannels 128 adjacent the top face 60. Thus, the first microchannels 128 are concentrated within the cooling interfaces 64 of the top face 60.

With continued reference to FIG. 4, the second manifold 204 extends between the second inlet port 208 at the second end 58 and the second outlet port 212. The second manifold 204 includes a second inlet conduit 220 that connects to a single branch 224 including a plurality of second microchannels 228, and then to a second outlet conduit 232. In some embodiments, the second manifold 204 may include a pair of branches 224 similar to the pair of branches 124. The second inlet conduit 220 is coupled to the second inlet port 208 and is fluidly coupled to an upstream end of the branch 224. Cooling fluid flows through the branch 224 and through the plurality of second microchannels 228. The second microchannels 228 are positioned adjacent the top face 60 of the cold plate 52 to increase heat transfer between the top face 60 and the cooling fluid. The branch 224 is fluidly coupled to the second outlet conduit 232, which is coupled to the second outlet port 212. The second manifold 204 therefore defines a portion of the second cooling loop 200. With continued reference to FIG. 4, the second manifold 204 includes a plurality of cooling stages 236 each positioned adjacent one of the cooling interfaces 64. In the illustrated embodiment, the second manifold 204 includes three cooling stages 236c, 236b, 236a to correspond with the three cooling interfaces 64c, 64b, 64a (FIG. 3). In embodiments with a different number of cooling interfaces 64, the second manifold 204 may include a corresponding number of cooling stages 236. Each cooling stage 236 includes a portion of the second microchannels 228 adjacent the top face 60. Thus, the second microchannels 228 are concentrated within the cooling interfaces 64 of the top face 60. As seen in FIG. 4, the branch 224 of the second manifold 204 is positioned between the pair of branches 124 of the first manifold 104.

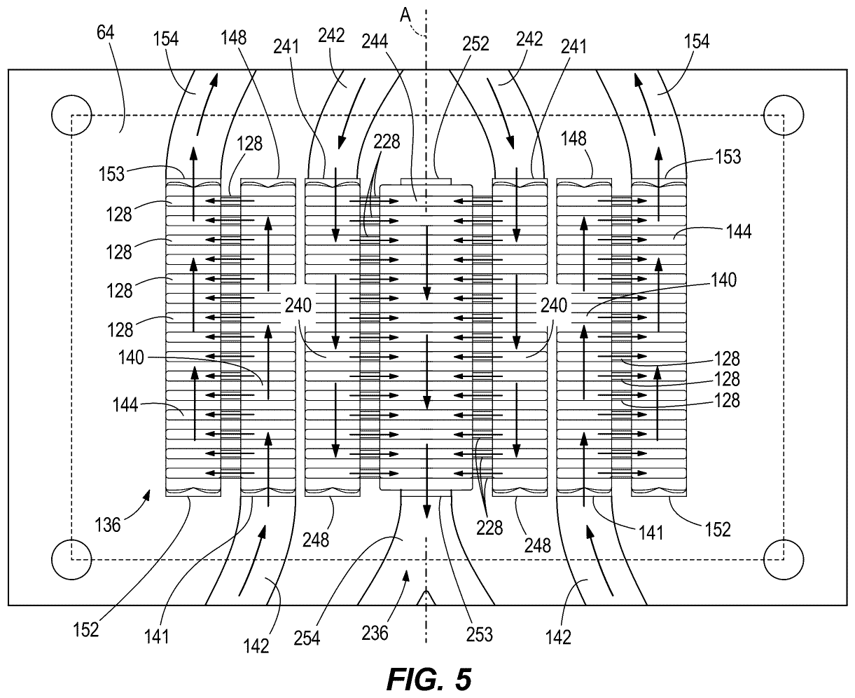

Turning to FIG. 5, the stages 136, 236 are shown in more detail. Each of the stages 136 of the first cooling loop 100 includes substantially the same components as the others. Additionally, within the stage 136, the pair of branches 124 are symmetrical and each include the same components. While the components are discussed in singular, the same components and fluid flow occurs in both branches 124. As seen in FIG. 5, the stage 136 includes an inner cool conduit 140 and an outer exhaust conduit 144 coupled by a portion of the plurality of first microchannels 128. The inner cool conduit 140 and outer exhaust conduit 144 each extend generally along the axis A and are generally aligned. The inner cool conduit 140 includes an inlet 141, coupled to receive fluid from a stage inlet conduit 142, and a closed downstream end 148. The first microchannels 128 are spaced along the axis A and extend between the conduit 140 and the conduit 144. The outer conduit 144 includes a closed upstream end 152 and an outlet 153 coupled to a stage outlet conduit 154. The inner cool conduit 140 and outer exhaust conduit 144 are generally aligned such that the inlet 141 of the inner cool conduit 140 is adjacent the closed upstream end 152 of the outer exhaust conduit, and the closed downstream end 148 is adjacent the outlet 153. Fluid flows through the stage inlet conduit 142, through the inlet 141 into the inner cool conduit 140. Fluid flows in the first direction through the inner cool conduit 140. The closed downstream end 148 forces the fluid through the first microchannels 128 in an outward direction (e.g., away from the axis A) and into the outer conduit 144. The closed upstream end 152 prevents backflow of the fluid within the outer exhaust conduit 144 and fluid therefore flows in the first direction, out the outlet 153 and into the stage outlet conduit 154.

With continued reference to FIG. 5, each of the stages 236 of the second cooling loop 200 includes substantially the same components as the other stages 236. The stage 236 includes a pair of outer cool conduits 240 and a central exhaust conduit 244 coupled by a portion of the plurality of second microchannels 228. In some embodiments, rather than sharing the central exhaust conduit 244, each outer cool conduit 240 may be coupled to one of a pair of inner exhaust conduits by a portion of the second microchannels 228. The outer cool conduits 240 and central exhaust conduit 244 each extend generally along the axis A and are generally aligned. The pair of outer cool conduits 240 each include an inlet 241, and a stage inlet conduit 242 divides to couple to each inlet 241. The pair of outer cool conduits 240 also each include a closed downstream end 248. The second microchannels 228 are spaced along the axis A and extend between the conduit 240 and the conduit 244. The central exhaust conduit 244 includes a closed upstream end 252 and an outlet 253 coupled to a stage outlet conduit 254. The outer cool conduits 240 and the central exhaust conduit 244 are generally aligned so the closed upstream end 252 is adjacent the inlets 241 and so the closed downstream ends 248 are adjacent the outlet 253. Fluid flows through the stage inlet conduit 242 and divides to flow through the inlets 241 into the pair of outer cool conduits 240. Fluid flows in the second direction through the cool conduits 240. The closed downstream ends 248 force the fluid through the second microchannels 228 in an inward direction (e.g., toward the axis A) and into the central conduit 244. The closed upstream end 252 prevents backflow of the fluid within the central exhaust conduit 244 and fluid therefore flows in the second direction, out the outlet 253 and into the stage outlet conduit 254.

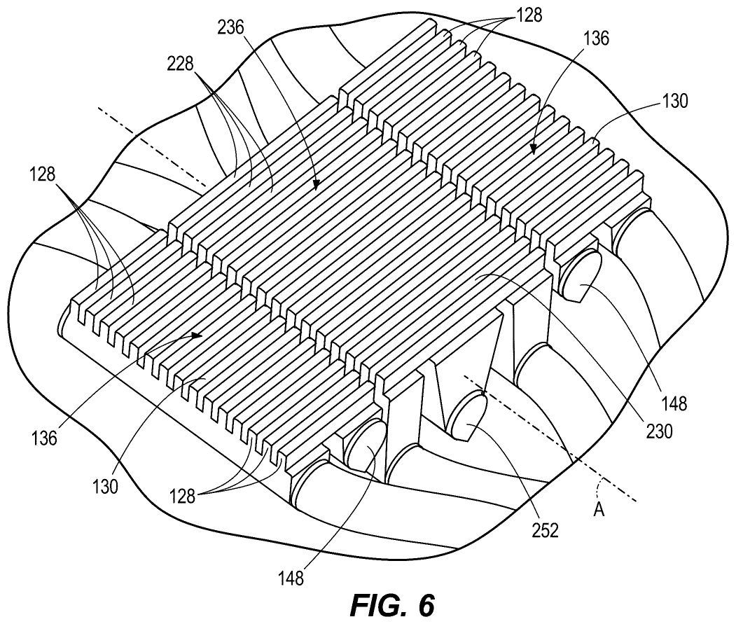

With reference to FIG. 6, the stages 136, 236 underlying one of the interfaces 64 are shown in more detail. Similar to FIG. 4, FIG. 6 illustrates the internal faces of the cold plate 52 that surround the passageways of the internal fluid system 68. In the illustrated embodiment, the first microchannels 128 and the second microchannels 228 are generally similar. The first microchannels 128 in each branch 124 form an array 130 extending between the inner cool conduit 140 and the outer exhaust conduit 144. The microchannels 128 may all be substantially the same width, depth, and height and may be evenly spaced along the axis A. In the illustrated embodiment, the first microchannels 128 overlie the conduits 140, 144 (i.e., the microchannels 128 extend from a farthest inward point of the inner conduit 140 to the farthest outward point of the outer conduit 144). Similarly, the second microchannels 228 form an array 230 extending between and overlying the pair of outer conduits 240 and the central exhaust conduit 244 (i.e., the microchannels 228 extend from a furthest outer point of one of the pair of outer conduits 240 to the furthest outer point of the other of the pair of outer conduits 240). The second microchannels 228 may be wider than the first microchannels 128.

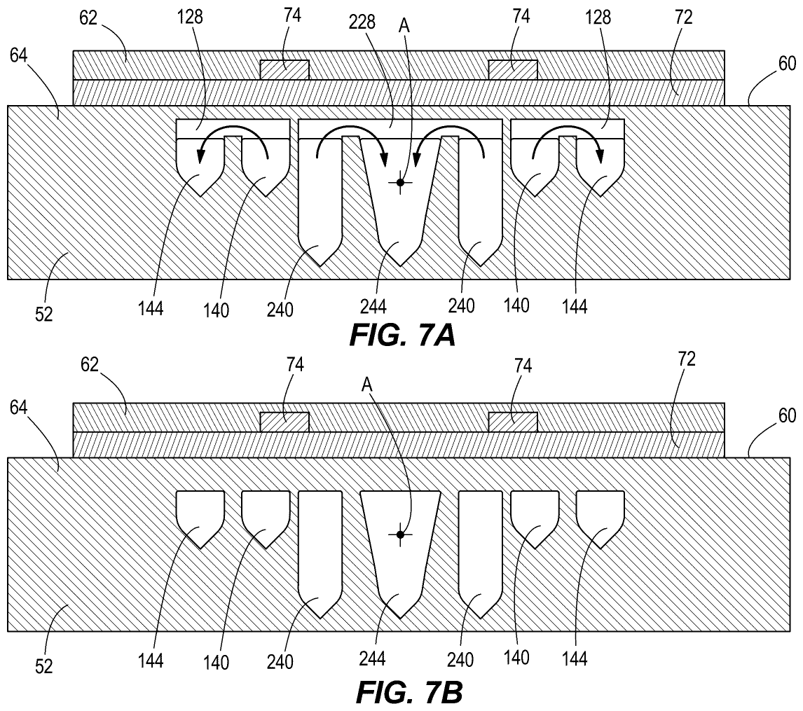

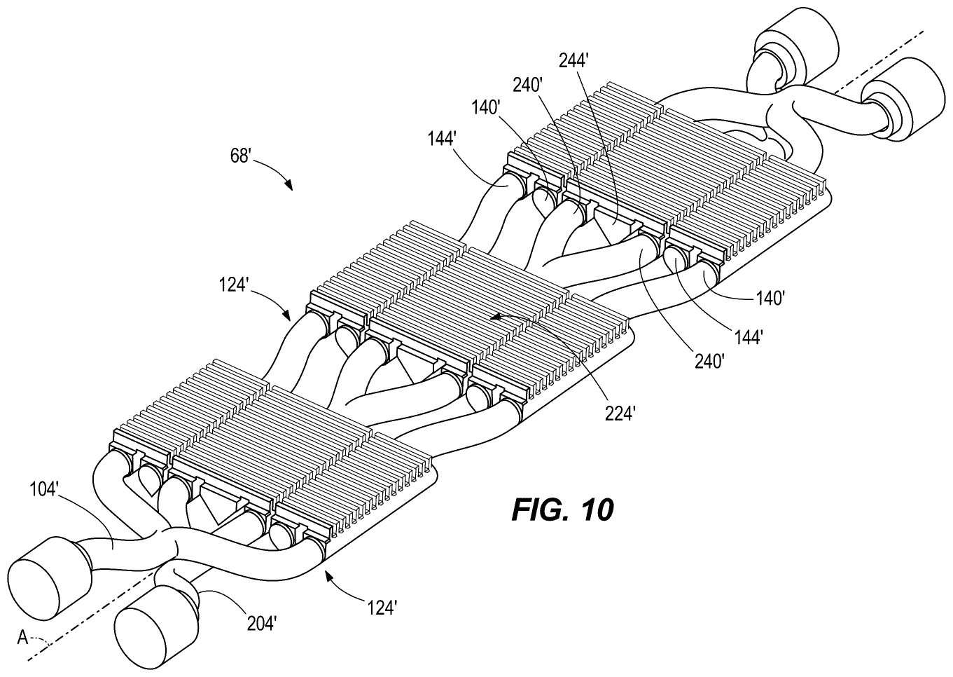

With reference to FIG. 6 and FIGS. 7A-7B, the conduits of the internal fluid system 68 may each include a cross-sectional shape generally similar to an inverted teardrop. In some embodiments, the teardrop shape may offer advantages for certain manufacturing methods. In some embodiments, the teardrop shape may increase the heat transfer by positioning more of the fluid adjacent the top face 60. In other embodiments, the conduits of the internal fluid system 68 may include other cross-sectional shapes including, but not limited to, conduits with circular cross-sections. In the illustrated embodiment, the cool conduits 140, 240 and the exhaust conduits 144, 244 have a cross-sectional shape in which the top of the teardrop extends up to the array of first microchannels 128. In other words, a plenum area may be formed to connect the curved conduit to the rectangular array. With continued reference to FIGS. 6 and 7A-7B, in the illustrated embodiment, the branch 224 of the second manifold 204 may extend further away from the top face 60 of the cold plate 52, and the plenum area in the conduits 240, 244 may be larger. In some embodiments, the offset between the branch 224 of the second manifold 204 and the branches 124 of the first manifold 104 may decrease heat transfer between fluid in the first cooling loop 100 and fluid in the second cooling loop 200. In some embodiments, the offset may offer advantages for certain manufacturing methods. In other embodiments, such as the embodiment shown in FIG. 10, the branch 224 may be in line with the pair of branches 124. In the illustrated embodiment, the first manifold 104 is configured to have the cool conduit 140 on an inner side and the second manifold 204 is configured to have the cool conduit 240 on an outer side. Thus, the cool conduits 140, 240 are adjacent each other and heat transfer between the cooling loops 100, 200 is minimized.

With reference to FIG. 7A, running fluid through the microchannels 128, 228 transfers heat from the portions of the cold plate 52 surrounding the microchannels 128, 228 into the fluid travelling through the microchannels 128, 228. FIGS. 7A and 7B schematically illustrate the electronic component 62 including a substrate 72 and a pair of sub-components 74 coupled to the substrate 72. In some embodiments, certain sub-components 74 may generate a higher heat load than other sub-components. In some embodiments, the electronic component 62 is configured such that the sub-components 74 with the higher heat load are positioned above and between the cool conduits 140, 240 to maximize heat transfer in that area and to distribute the heat load between the first cooling loop 100 and the second cooling loop 200. Thus, the internal fluid system 68 includes complex geometry to maximize the heat transfer and efficiency of the cold plate 52.

The cold plate 52 can be additively manufactured. An additive manufacturing (AM) process is where a component is built layer-by-layer by successive deposition of material. AM is an appropriate name to describe the technologies that build 3D objects by adding layer-upon-layer of material, whether the material is metal or non-metal. AM technologies can utilize a computer, 3D modeling software (Computer Aided Design or CAD), machine equipment, and layering material. Once a CAD sketch is produced, the AM equipment can read in data from the CAD file and lay down or add successive layers of liquid, powder, sheet material or other material, in a layer-upon-layer fashion to fabricate a 3D object. It should be understood that the term “additive manufacturing” encompasses many technologies including subsets like 3D Printing, Rapid Prototyping (RP), Direct Digital Manufacturing (DDM), layered manufacturing and additive fabrication. Non-limiting examples of additive manufacturing that can be utilized to form an additively-manufactured component include powder bed fusion, vat photopolymerization, binder jetting, material extrusion, directed energy deposition, material jetting, electric pulses through a laser induced plasma channel, or sheet lamination. In the illustrated embodiment, the cold plate 52 is formed using Direct Metal Laser Sintering (DMLS). Metal powder (without binders or fluxing agents) is positioned within a layer according to a CAD model and is completely melted by a high-power laser beam, creating a solid layer of material that is connected to the layer below. Subsequent layers are added and melted until the part is completed, creating a metal blank including the desired internal geometry defining the internal fluid system 68. In some embodiments, the metal blank may be heat treated to relieve internal stresses and unify the part. Additionally, the metal blank may be heat treated, milled, or otherwise processed to create the desired surface finish. The resulting cold plate 52 therefore has the complex internal geometry, high strength, and a smooth surface finish to create efficient cooling of the electronic components 62. In the illustrated embodiment, the cold plate 52 is formed from an aluminum alloy. In some embodiments, other metal materials may be used. In some embodiments, the cold plate 52 may be formed from non-metal materials and may include metal plating. In still further embodiments, the cold plate 52 may be manufactured in other ways including, but not limited to, CNC milling.

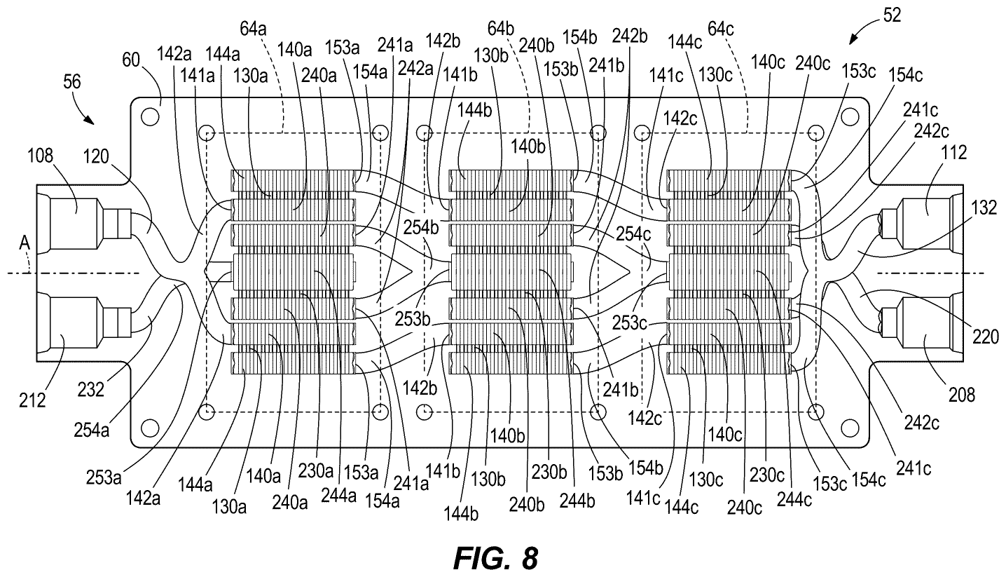

With reference now to FIG. 8, the cold plate 52 has a series configuration. The cooling interfaces 64 include a first end interface 64a, a middle interface 64b, and a second end interface 64c. The stages 136 of the first cooling loop 100 similarly includes stages 136a, 136b, 136c, and the stages 236 of the second cooling loop 200 includes stages 236a, 236b, 236c each associated with the cooling interfaces 64a, 64b, 64c positioned adjacent thereto. The first manifold 104 has a series configuration in the first direction, since all fluid must pass through the stage 136a before continuing to the stage 136b and then to the stage 136c. Similarly, the second manifold 204 has a series configuration in the second direction, since all fluid must pass through the stage 236c before continuing to the stage 236b and then to the stage 236a afterwards. The opposing directions of the cooling loops 100, 200 allows for balanced heat transfer efficiency of the cooling interface 64 when both cooling loops 100, 200 are operational.

In operation of the first cooling loop 100, fluid flows into the first manifold 104 of the cold plate 52 through the first inlet port 108. The fluid enters the first inlet conduit 120 and splits into the pair of branches 124. In other words, fluid from the first inlet conduit 120 divides and flows into a pair of stage inlet conduits 142a. Each stage inlet conduit 142a connects to an inner cool conduit 140a via a stage inlet 141a. Fluid flows from the inner cool conduit 140a through the array 130a of the first microchannels 128 and to the outer exhaust conduit 144a. Fluid then flows in the first direction out the outlet 153a into the outlet conduit 154a of the stage 136a. The outlet conduit 154a of the stage 136a, adjacent the first end interface 64a, connects to the stage inlet conduit 142b of the stage 136b, adjacent the middle interface 64b. Fluid flows through the stage 136b generally in the first direction, similar to the stage 136a, flowing through the inlet 141b into the inner cool conduit 140b, through the portion 130b of first microchannels 128, through the outer exhaust conduit 144b, and through the outlet 153b to the outlet conduit 154b. The outlet conduit 154b couples to the inlet conduit 142c of the stage 136c, adjacent the second end interface 64c. Again, fluid flows generally in the first direction, through the inlet 141c, the inner cool conduit 140c, the portion 130c of the first microchannels 128, and the outer conduit 144c, and through the outlet 153c to the outlet conduit 154c. The outlet conduit 154c of each branch 124 join together and fluid flows from the branches 124 to the first outlet conduit 132 of the first cooling loop 100. Fluid then exits the cold plate through the first outlet port 112.

In operation of the second cooling loop 200, fluid flows into the second manifold 204 of the cold plate 52 through the second inlet port 208. The fluid enters the second inlet conduit 220 and into the branch 224. Since the second inlet port 208 is positioned adjacent the second end 58 of the cold plate 52, the second cooling loop 200 extends through the stages 236c, 236b, 236a in reverse order. Thus, fluid from the second inlet conduit 220 flows into the stage inlet conduit 242c which divides to connect to each of the inlets 241c of the stage 236c, adjacent the interface 64c. Fluid flows through the inlets 241c and into the pair of outer cool conduits 240c, then flows inwardly through the array 230c of the second microchannels 228, transferring heat from the top face 60 within the cooling interface 64c to the fluid. Fluid then travels through the central exhaust conduit 244c and to the stage outlet conduit 254c via the outlet 253c. The stage outlet conduit 254c couples to the stage inlet conduit 242b of the stage 236b, adjacent the middle cooling interface 64b. Fluid flows through the stage 236b generally in the second direction, similar to the stage 236c. Fluid flows through the stage inlet conduit 242b which divides to flow through the pair of inlets 241b. Fluid flows into the pair of outer cool conduits 240b, through the array 230b of second microchannels 228, transferring heat from the middle cooling interface 64b to the fluid. Fluid then flows through the central exhaust conduit 244b, and through the outlet 253b to the stage outlet conduit 254b. The stage outlet conduit 254b couples to the stage inlet conduit 242a of the stage 236a, adjacent the first end interface 64a. Again, fluid flows generally in the second direction, through the inlets 241a, the outer cool conduits 240a, the array 230a of the second microchannels 228, and the central exhaust conduit 244a, and through the outlet 253a to the outlet conduit 254a. The outlet conduit 254a couples to the outlet conduit 232 of the second cooling loop 200. Fluid then exits the cold plate 52 through the second outlet port 212.

With reference to FIGS. 4-8, the internal fluid system 68 therefore transfers heat away from the electronic components 62 coupled to the cooling interfaces 64 of the top face 60. As discussed above, the internal fluid system 68 allows for two redundant cooling loops 100, 200 to separately transfer heat away from the electronic components 62.

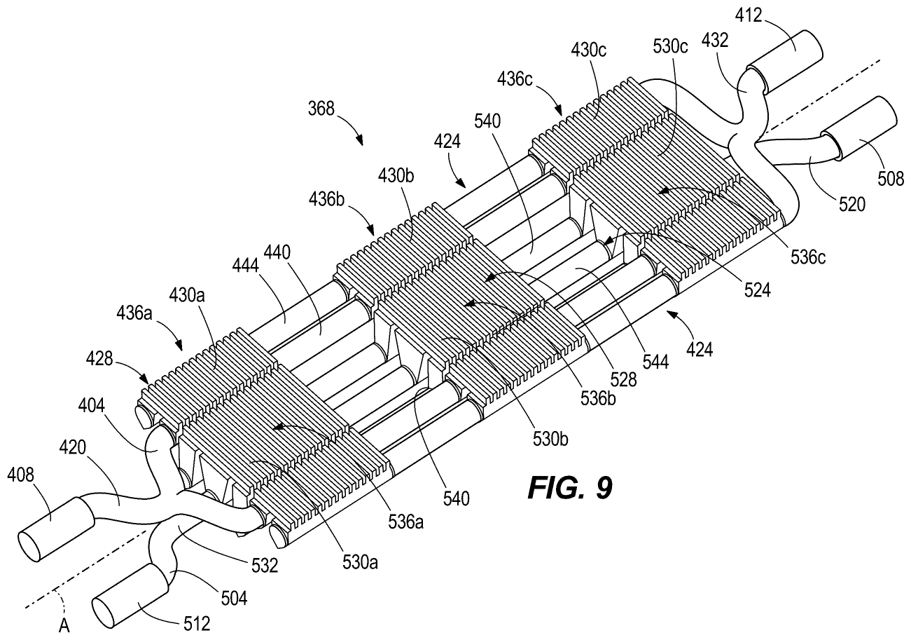

Turning now to FIG. 9, an alternate embodiment of an internal fluid system 368 for use in a cold plate is illustrated. The internal fluid system 368 may be formed in a cold plate substantially the same as the cold plate 52 and extending along a longitudinal axis A. The internal fluid system 368 has a plurality of internal passageways defining a first cooling manifold 404 and a second cooling manifold 504. As discussed above, the first cooling manifold 404 may form a portion of the first cooling loop 100, and the second cooling manifold 504 may form a portion of the second cooling loop 200. The first manifold 404 includes a first inlet port 408, a first outlet port 412, a first inlet conduit 420, a pair of branches 424, a plurality of first microchannels 428, and an outlet conduit 432. The first manifold 404 may have a parallel configuration. The first manifold 404 includes stages 436a, 436b, 436c associated with the cooling interfaces 64a, 64b, 64c of the cold plate 52. In the illustrated configuration, each branch 424 of the first manifold 404 includes a single inner cool conduit 440 and a single outer exhaust conduit 444 extending through all of the three stages 436a, 436b, 436c. The inner cool conduit 440 is connected to the outer exhaust conduit 444 within each of the stages 436a, 436b, 436c by respective arrays 430a, 430b, 430c of the first microchannels 428. Fluid therefore flows into the inner cool conduit 440 in the stage 436a. A portion of the fluid flows outward through the array 430a of first microchannels 428 to the outer exhaust conduit 444 and travels in the first direction along the outer exhaust conduit 444 through the remaining stages 436b, 436c to the outlet conduit 432. Another portion of the fluid exits the stage 436a within the inner cool conduit 440 and enters the next stage 436b. Again, a portion of fluid travels across the array 430b of first microchannels 428 and then in the first direction along the outer exhaust conduit 444 to the outlet conduit 432. Another portion of fluid continues on in the inner cool conduit 440 into the next stage 436c. At this point, a closed downstream end (not shown) causes the remainder of the fluid to travel through the array 430c of first microchannels 428 to the outer exhaust conduit 444 and on to the outlet port 412 via the outlet conduit 432.

With continued reference to FIG. 9, the second manifold 504 includes a second inlet port 508, a second outlet port 512, a second inlet conduit 520, a branch 524, a plurality of second microchannels 528, and an outlet conduit 532. The second manifold 504 may also have a parallel configuration. The branch 524 of the second manifold 504 includes stages 536a, 536b, 536c associated with the cooling interfaces 64a, 64b, 64c of the cold plate 52. In the illustrated configuration, the branch 524 includes a pair of outer cool conduits 540 and a central exhaust conduit 544 each of which extend beneath all of the three stages 536a, 536b, 536c. The pair of outer cool conduits 540 are connected to the central exhaust conduit 544 within each of the stages 536a, 536b, 536c by arrays 530a, 530b, 530c of the second microchannels 528. Fluid therefore flows into the pair of cool conduits 540 in the stage 536c. A portion of the fluid flows inward through the array 530c of second microchannels 528 to the central exhaust conduit 544 and travels in the second direction along the central exhaust conduit 544 through the remaining stages 536b, 536a to the outlet conduit 532. Another portion of the fluid exits the stage 536c within the pair of outer cool conduit 540 and enters the next stage 536b. Again, a portion of fluid travels inwardly, through the array 530b of the second microchannels 528, and then in the second direction along the outer exhaust conduit 544 to the outlet conduit 532. Another portion of fluid continues on in the pair of outer cool conduit 540 into the next stage 536a. At this point, a closed downstream end (not shown) in each of the outer cool conduits 540 causes the remainder of the fluid to travel through the array 530a of the second microchannels 528 to the central exhaust conduit 544 and on to the outlet port 512 via the outlet conduit 532.

FIG. 10 illustrates another embodiment of an internal fluid system 68′ for use in a cold plate. The internal fluid system 68′ may be formed in a cold plate substantially the same as the cold plate 52 and extending along a longitudinal axis A. The internal fluid system 68′ may be similar to the internal fluid system 68 illustrated in FIG. 4 and only differences between the systems are discussed herein. The branch 224′ of the second manifold 204′ and the branches 124′ of the first manifold 104′ are aligned instead of offset. In other words, the conduits 240′, 244′ extend the same distance away from the top face 60 of the cold plate 52 as the conduits 140′, 144′. The plenum area in the conduits 240′, 244′ may be approximately the same size as the plenum area in the conduits 140′, 144′. While the illustrated configuration is similar to the ‘series’ configuration of the internal fluid system 68, the aligned conduits may also be used in a ‘parallel’ configuration like the internal fluid system 368 of FIG. 9.

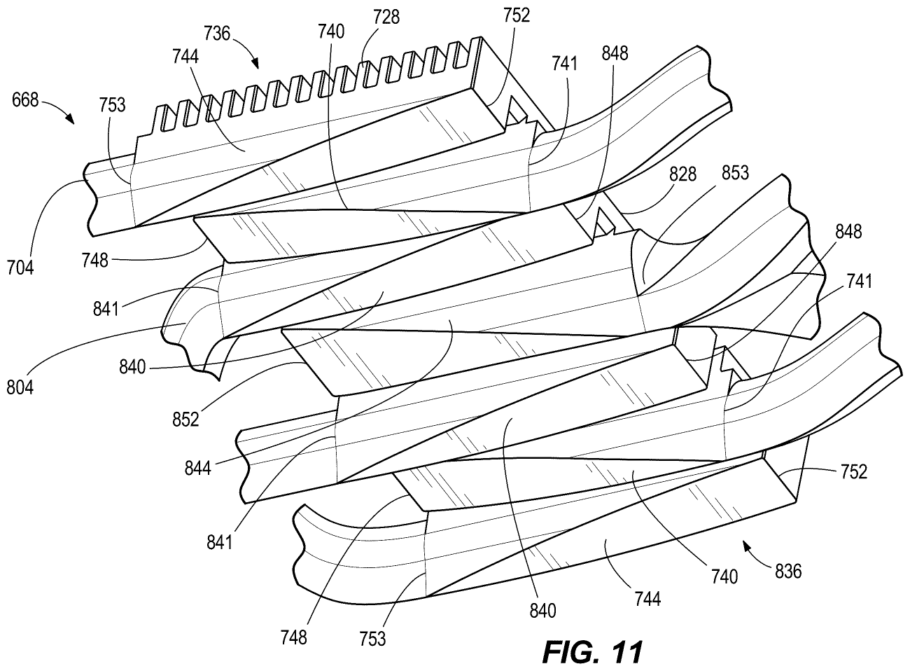

FIG. 11 illustrates yet another embodiment of an internal fluid system 668 for use in a cold plate. The internal fluid system 668 may be formed in a cold plate assembly substantially the same as the cold plate 52 extending along a longitudinal axis A. The illustrated internal fluid system 668 may be generally similar to the internal fluid system 68 of FIG. 4, and only differences are discussed herein. FIG. 11 illustrates a lower view of one of the stages 736, 836 of the internal fluid system 668. Each of the stages 736, 836 may be similar to the illustrated stage 736, 836. The conduits in the stage are tapered, or in other words, each conduit has a varying cross-section along the axis A.

In each stage 736 of the first cooling manifold 704, the inner cool conduits 740 have a first cross sectional area at the inlet 741 and a second cross-sectional area at the closed downstream end 748. The second cross-sectional area is smaller than the first cross-sectional area. The inner cool conduits 740 are tapered along the axis A in a first direction. In the illustrated embodiment, the inner cool conduits 740 taper steadily or linearly between the inlet 741 and the downstream end 748 so that each subsequent cross-sectional area is smaller than the previous. In other embodiments, the other rates of cross-sectional variance may be used. The tapering cross-sectional area of the cool conduits 740 forces the fluid through the attached microchannels 728 and into the outer warm conduits 744. The outer warm conduits 744 have a first cross sectional area at the closed upstream end 752 and a second cross sectional area at the outlet 753. The second cross sectional area is larger than the first cross sectional area. The outer warm conduits 744 are tapered along the axis A in a second direction, opposite the first direction. In the illustrated embodiment, the taper of the outer warm conduits 744 follow a similar linear profile to the taper of the inner cool conduits 740 but reversed. In the illustrated embodiment, the closed downstream end 748 and the closed upstream end 752 are completely tapered so only the plenum area of the microchannel 728 remains. The combination of tapering in the conduits 740, 744 creates a more even distribution along the axis A of fluid flow through the microchannels 728. Thus, the cooling provided to the top face 60 within stage 736 is more evenly distributed.

Similarly, in each stage 836 second cooling manifold 804, the outer cool conduits 840 have a first cross sectional area at the inlets 841 and a second cross-sectional area at the closed downstream ends 848. The second cross-sectional area is smaller than the first cross-sectional area. The outer cool conduits 840 are tapered along the axis A in the second direction. In the illustrated embodiment, the outer cool conduits 840 taper steadily or linearly between the inlets 841 and the downstream ends 848 so that each subsequent cross-sectional area is smaller than the previous. The taper profile of the outer cool conduits 840 may be the same as the taper profile of the outer warm conduits 744 of the first cooling manifold 704. In other embodiments, the other rates of cross-sectional variance may be used. The tapering cross-sectional area of the outer cool conduits 840 forces the fluid through the attached microchannels 828 and into the inner warm conduit 844. The inner warm conduit 844 has a first cross sectional area at the closed upstream end 852 and a second cross sectional area at the outlet 853. The second cross sectional area is larger than the first cross sectional area. The inner warm conduits 844 are tapered along the axis A in the first direction, opposite the second direction. In the illustrated embodiment, the taper of the inner warm conduit 844 may be the same as the taper profile of the inner cool conduits 740 of the stage 736. In the illustrated embodiment, the closed downstream end 848 and the closed upstream end 852 are completely tapered so only the plenum area of the microchannel 828 remains. The combination of tapering in the conduits 840, 844 creates a more even distribution along the axis A of fluid flow through the microchannels 828. Thus, the cooling provided to the top face 60 within stage 836 is more evenly distributed. In some embodiments, all of the stages 736, 836 include tapered conduits. In some embodiments, only some of the stages 736, 836 include tapered conduits. In some embodiments, only the first manifold 704 or the second manifold 804 may include tapered conduits. In other embodiments, other variations may be implemented.

Embodiments disclosed herein are primarily for exemplary purposes. It should be understood that alternative embodiments or various combinations of features described herein may be implemented.

Various features and advantages of the embodiments described herein are set forth in the following claims.

What is claimed is:

1. A cold plate for cooling an electronic component, the cold plate comprising:
a first end;
a second end, opposite the first end;
a top face extending between the first end and the second end, the top face configured to engage the electronic component;
a first set of conduits extending between the first end and the second end, the first set of conduits including
a first inlet conduit,
a first outlet conduit, and
at least one first microchannel between the first inlet conduit and the first outlet conduit;
a second set of conduits extending between the first end and the second end, the second set of conduits including
a second inlet conduit,
a second outlet conduit,
at least one second microchannel between the second inlet conduit and the second outlet conduit;
wherein the first set of conduits is fluidly isolated from the second set of conduits.

2. The cold plate of claim 1, wherein the first set of conduits is part of a first cooling loop including a first pump, and the second set of conduits is part of a second cooling loop including a second pump.

3. The cold plate of claim 1, wherein the first end of the cold plate includes a first inlet port connected to the first inlet conduit and a second outlet port connected to the second outlet conduit.

4. The cold plate of claim 3, wherein the second end of the cold plate includes a first outlet port connected to the first outlet conduit and a second inlet port connected to the second inlet conduit.

5. The cold plate of claim 1, wherein the first set of conduits includes a pair of first branches and the second set of conduits includes a second branch, and wherein the second branch is positioned between the pair of first branches.

6. The cold plate of claim 5, wherein the first set of conduits includes three stages arranged in series, wherein each stage includes an inner cool conduit and an outer exhaust conduit connected by a plurality of first microchannels, and wherein the outer exhaust conduit of the previous stage is fluidly coupled to the inner cool conduit of the subsequent stage.

7. The cold plate of claim 6, wherein the second set of conduits includes three stages arranged in series, wherein each stage includes a pair of outer cool conduits and an inner exhaust conduit connected by a plurality of second microchannels, and wherein the inner exhaust conduit is fluidly coupled to the pair of cool conduits of the subsequent stage.

8. The cold plate of claim 7, wherein the inner cool conduit of each of the first branches of the first set of conduits is adjacent to one of the pair of cool conduits of the second set of conduits.

9. The cold plate of claim 1, wherein the electronic component is positioned on the top face to overlie a portion of the first microchannel and a portion of the second microchannel.

10. The cold plate of claim 1, wherein the cold plate is a single unitary piece and the first set of conduits and the second set of conduits are formed by negative space of the cold plate.

11. A cooling system for cooling avionics, the cooling system comprising:
a cold plate having a first end, a second end, and a top face configured to engage one or more avionic components;
a first cooling loop including a first pump and a first set of conduits extending through the cold plate; and
a second cooling loop including a second pump and a second set of conduits extending through the cold plate;
wherein fluid in the first cooling loop travels through the cold plate in a first direction and fluid in the second cooling loop travels through the cold plate in a second direction, opposite the first direction.

12. The cooling system of claim 11, wherein the first cooling loop enters the cold plate on the first end, and wherein the second cooling loop enters the cold plate from the second end.

13. The cooling system of claim 11, wherein the first direction extends from the first end to the second end and the second direction extends from the second end to the first end.

14. The cooling system of claim 11, wherein the first cooling loop is fluidly isolated from the second cooling loop.

15. The cooling system of claim 11, wherein the first cooling loop is operable independently from the second cooling loop.

16. The cooling system of claim 11, wherein the first cooling loop provides a first level of heat transfer and the second cooling loop provides a second level of heat transfer, wherein the avionic components have a required level of heat transfer to cool the avionic component, and wherein the first level of heat transfer and the second level of heat transfer are each higher than the required level of heat transfer.

17. The cooling system of claim 11, wherein a rate of fluid flow through the first set of conduits is the same as a rate of fluid flow through the second set of conduits.

18. The cooling system of claim 11, wherein the first set of conduits includes three stages and wherein each stage includes an inlet conduit, an outlet conduit, and a plurality of microchannels coupled between the inlet conduit and the outlet conduit.

19. The cooling system of claim 11, wherein the first cooling loop provides sufficient heat transfer to cool the avionic components when the second cooling loop is not operating.

20. A method for cooling an avionic component, the method comprising:
mounting the avionic component to a top face of a cold plate;
circulating a first cooling fluid through a first loop, including
activating a first pump to circulate the first cooling fluid, and
circulating the first cooling fluid through a set of first conduits in the cold plate to transfer heat from the avionic component through the top face to the first cooling fluid;
circulating a second cooling fluid through a second loop, including
activating a second pump to circulate the second cooling fluid, and
circulating the second cooling fluid through a set of second conduits in the cold plate to transfer heat from the avionic component through the top face to the second cooling fluid;
wherein the second loop is fluidly isolated from the first loop.
